(19) United States
(12) Patent Application Publication
(10) Pub. No.: US 2011/0103418 A1
(43) Pub. Date: May 5, 2011

(54) SUPERLUMINESCENT DIODES BY CRYSTALLOGRAPHIC ETCHING

(75) Inventors: Matthew T. Hardy, Goleta, CA (US); You-Da Lin, Goleta, CA (US); Hiroaki Ohta, Goleta, CA (US); Steven P. DenBaars, Goleta, CA (US); James S. Speck, Goleta, CA (US); Shuji Nakamura, Santa Barbara, CA (US); Kathryn M. Kelchner, Santa Barbara, CA (US)

(73) Assignee: THE REGENTS OF THE UNIVERSITY OF CALIFORNIA, Oakland, CA (US)

(21) Appl. No.: 12/913,638

(22) Filed: Oct. 27, 2010

Related U.S. Application Data
(60) Provisional application No. 61/257,752, filed on Nov. 3, 2009.

(51) Int. Cl. H01S 5/323; H01L 33/22; H01L 21/302

(52) U.S. Cl. 372/44.01; 257/98; 438/29; 257/E33.074; 257/E21.214

(57) ABSTRACT

An optoelectronic device, comprising an active region and a waveguide structure to provide optical confinement of light emitted from the active region; a pair of facets on opposite ends of the device, having opposite surface polarity; and one of the facets which has been roughened by a crystallographic chemical etching process, wherein the device is a nonpolar or semipolar (Ga,In,Al,B)N based device.

### CROSS REFERENCE TO RELATED APPLICATIONS

This application claims priority under 35 U.S.C. §119(e) to co-pending and commonly-assigned U.S. Provisional Patent Application Ser. No. 61/257,752 entitled “SUPERLUMINESCENT DIODES BY CRYSTALLOGRAPHIC ETCHING,” filed on Nov. 3, 2009, by Matthew T. Hardy, You-da Lin, Hiroaki Ohta, Steven P. DenBaars, James S. Speck, and Shuji Nakamura, attorney's docket number 30794.330-US-P1 (2010-113), which application is incorporated by reference herein.

This application is related to the following co-pending and commonly-assigned U.S. patent applications:

U.S. Utility application Ser. No. 10/581,940, filed on Jun. 7, 2006, now U.S. Pat. No. 7,704,763, issued Apr. 27, 2010, by Tetsuo Fujii, Yan Gao, Evelyn. L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C Section 365(c) of PCT Application Serial No. US2003/039211, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063);

U.S. Utility application Ser. No. 12/030,117, filed on Feb. 12, 2008, by Daniel F. Feezell, Mathew C. Schmidt, Kwang Choong Kim, Robert M. Farrell, Daniel A. Cohen, James S. Speck, Steven P. DenBaars, and Shuji Nakamura, entitled “Al(x) Ga(1-x)N-CLADDING-FREE NONPOLAR GAN-BASED LASER DIODES AND LEDS,” attorneys' docket number 30794.222-US-U1 (2007-424), which application claims the benefit under 35 U.S.C. Section 119(e) of U.S. Provisional Application Ser. No. 60/889,510, filed on Feb. 12, 2007, by Daniel F. Feezell, Mathew C. Schmidt, Kwang Choong Kim, Robert M. Farrell, Daniel A. Cohen, James S. Speck, Steven P. DenBaars, and Shuji Nakamura, entitled “Al(x)Ga(1-x)N-CLADDING-FREE NONPOLAR GAN-BASED LASER DIODES AND LEDS,” attorneys' docket number 30794.222-US-P1 (2007-424-1);

U.S. Utility application Ser. No. 12/030,124, filed on Feb. 12, 2008, by Robert M. Farrell, Mathew C. Schmidt, Kwang Choong Kim, Hisashi Masui, Daniel F. Feezell, Daniel A. Cohen, James S. Speck, Steven P. DenBaars, and Shuji Nakamura, entitled “OPTIMIZATION OF LASER BAR ORIENTATION FOR NONPOLAR (Ga,Al,In,B)N DIODE LASERS,” attorneys' docket number 30794.223-US-U1 (2007-425), which application claims the benefit under 35 U.S.C. Section 119(e) of U.S. Provisional Application Ser. No. 60/889,516, filed on Feb. 12, 2007, by Robert M. Farrell, Mathew C. Schmidt, Kwang Choong Kim, Hisashi Masui, Daniel F. Feezell, Daniel A. Cohen, James S. Speck, Steven P. DenBaars, and Shuji Nakamura, entitled “OPTIMIZATION OF LASER BAR ORIENTATION FOR NONPOLAR (Ga,Al,In,B)N DIODE LASERS,” attorneys' docket number 30794.223-US-P1 (2007-425-1); and

U.S. Utility application Ser. No. 12/833,607, filed on Jul. 9, 2010, by Robert M. Farrell, Matthew T. Hardy, Hiroaki Ohta, Steven P. DenBaars, James S. Speck, and Shuji Nakamura, entitled “STRUCTURE FOR IMPROVING THE MIRROR FACET CLEAVING YIELD OF (Ga,Al,In,B)N LASER DIODES GROWN ON NONPOLAR OR SEMIPOLAR (Ga,Al,In,B)N SUBSTRATES,” attorney's docket number 30794.319-US-P1 (2009-762-1), which application claims the benefit under 35 U.S.C. Section 119(e) of U.S. Provisional Application Ser. No. 61/224,368 filed on Jul. 9, 2009, by Robert M. Farrell, Matthew T. Hardy, Hiroaki Ohta, Steven P. DenBaars, James S. Speck, and Shuji Nakamura, entitled “STRUCTURE FOR IMPROVING THE MIRROR FACET CLEAVING YIELD OF (Ga,Al,In,B)N LASER DIODES GROWN ON NONPOLAR OR SEMIPOLAR (Ga,Al,In,B)N SUBSTRATES,” attorney's docket number 30794.319-US-P1 (2009-762-1);

which applications are incorporated by reference herein.

### BACKGROUND OF THE INVENTION

1. Field of the Invention

This invention relates to fabrication of a low reflectance facet suitable for production of nonpolar (Ga,In,Al,B)N based superluminescent diodes (SLDs).

2. Description of the Related Art

(Note: This application references a number of different publications as indicated throughout the specification by one or more reference numbers within parentheses, e.g., (x). A list of these different publications ordered according to these reference numbers can be found below in the section entitled “References.” Each of these publications is incorporated by reference herein.)

Several techniques have been used to fabricate SLDs in various semiconductor systems, particularly GaAs and InP based systems. The SLD requires a semiconductor device to provide gain and one non-reflecting facet to prevent lasing action. Techniques used to fabricate the non-reflective facet include a passive absorber region, an anti-reflective coating and an angled or fiber coupled facet (or an angled active region), among others (see e.g., (13)-(16)). Passive absorbers require additional wafer real estate, effective anti-reflective coatings require multiple layers and are relatively expensive to fabricate, and angled facets require additional processing steps that are less compatible with mass production than, for example, a batch wet etching technique.

### SUMMARY OF THE INVENTION

The present invention has invented a process to fabricate superluminescent diodes (SLDs) from a (Ga,In,Al,B)N laser diode (LD) grown on nonpolar GaN. Commercially available (Ga,In,Al,B)N LDs are typically grown on c-plane substrates. Polarization related electric fields require thin quantum wells (typically less than 4 nm) to avoid spatial separation of the electron and hole wave functions within the well. Thick AlGaN films or AlGaN/GaN strained-layer-superlattices form cladding layers and provide optical confinement.

LDs grown on the nonpolar m-planes and a-planes (Ga,In,Al,B)N are free from polarization related effects. This allows growth of wider quantum wells (e.g., wider than 4 nm), which can have a larger contribution towards optical confinement, allowing the demonstration of AlGaN cladding free LDs (1),(2). The absence of AlGaN leads to simplified manufacturing by removing reactor instabilities due to Al precursor parasitic reactions. Also, unbalance biaxial strain in nonpolar (Ga,In,Al,B)N causes a splitting of the heavy hole and light hole valance bands, providing lower threshold current densities relative to bi-axially strained c-plane (Ga,In,Al,B)N (3).

Threshold current densities for laser stripes oriented along the c-axis are lower than for stripes along the a-axis (4). As such, nonpolar LDs must be cleaved exposing the polar c-plane facet as the cavity mirror in order to maximize gain, efficiency and output power.

The N-polar face of c-plane GaN has been shown to etch crystallographically under both photo-electrical-chemical (PEC) (4) etching conditions and wet etching chemistries such as KOH (5). This technology is commonly used to enhance light extraction on the back side of (Ga,In,Al,B)N light-emitting diodes (LEDs) through the formation of hexagonal pyramids (6).

SLDs make use of amplified spontaneous emission to generate unidirectional high power optical output at similar orders of magnitude to a LD. Without a strong enough optical cavity, a SLD cannot generate enough optical feedback to show true lasing action. Without lasing, there is no mode selection resulting in spectral width an order of magnitude larger than that for LDs and low coherence. Broad spectral width greatly reduces the risk of eye damage associated with LDs, and low coherence reduces coherence noise or “speckle”. The absence of strongly localized light emission helps prevent catastrophic optical damage (COD) failure that is a common failure mechanism in LDs. These properties make SLDs ideally suited for applications in pico projectors—where directional, high power emission is necessary and eye damage risk and coherence noise is detrimental—as well as retinal scanning displays (without the requirement for high power). SLDs have been previously demonstrated in GaAs (7) and other material systems using passive absorbers, waveguide extraction, angled facets and antireflection coatings, among others, to prevent feedback at one end of the device.

Using crystallographic wet or PEC etching to fabricate hexagonal pyramids on the Nitrogen face (N-face) (c⁻ facet) of the c-plane facets of nonpolar (Ga,In,Al,B)N allows efficient light extraction at the N-face (8). This provides the non-reflecting facet necessary for the formation of a SLD. Using a PEC or wet etching process provides a low cost, easily mass producible technique for the fabrication of SLDs, without the wasted wafer space required for a passive absorber. Controlling the progression of the hexagonal pyramid formation by adjusting the etch time, PEC illumination power, and etch electrolyte concentration allows control of the amount of optical loss. This allows the process to be easily adapted to ensure superluminescence for (Ga,In,Al,B)N SLDs which have different optical gain, especially for devices emitting at different wavelengths.

Thus, to overcome the limitations in the prior art, and to overcome other limitations that will become apparent upon reading and understanding the present specification, the present invention discloses a nonpolar or semipolar III-Nitride based optoelectronic device (e.g., SLD), comprising an active region; a waveguide structure to provide optical confinement of light emitted from the active region; and a first facet and a second facet on opposite ends of the waveguide structure, wherein the first facet and the second facet have opposite surface polarity and the first facet has a roughened surface.

The first facet may comprise a roughened c⁻ facet, c⁻ plane or N-face of the III-Nitride device, and the second facet may comprise a c⁺ facet, c⁺ plane, Ga-face, or III-face of the III-Nitride device.

The roughened surface may be a wet etched surface, a crystallographically etched surface, or a PEC etched surface, for example. The roughened surface may be a roughened cleaved surface, and the second facet may have a cleaved surface.

The roughened surface may prevent optical feedback along an in-plane c-axis of the waveguide structure.

The roughened surface may comprise structures (e.g., hexagonal pyramids) having a diameter and height sufficiently close to a wavelength of the light that the pyramids scatter the light out of the SLD. The pyramids may have a diameter between 0.1 and 1.6 micrometers, or between 0.1 and 10 micrometers, or 10 micrometers or more, for example.

The SLD may have an output power of at least 5 milliwatts (mW).

The roughened surface may be such that no lasing peaks are observed in an emission spectrum of the SLD for drive currents up to 315 mA, wherein lasing is observed in an identical structure without the roughened surface for drive currents above 100 mA.

The roughened surface may be such that an output power of the SLD increases exponentially with increasing drive current, in a linear gain regime of the SLD.

The roughened surface may be such that a full width at half maximum (FWHM) of the light emitted by the SLD is at least 10 times larger than without the roughening. For example, the SLD may emit blue light and the roughened surface may be such that a FWHM of the light is greater than 9 nm.

The waveguide structure may utilize index guiding or gain guiding to reduce internal loss.

The present invention further discloses a method of fabricating a nonpolar or semipolar III-Nitride based optoelectronic device, comprising obtaining a first nonpolar or semipolar III-Nitride based optoelectronic device comprising an active region, a waveguide structure to provide optical confinement of light emitted from the active region, and a first facet and a second facet on opposite ends of the waveguide structure, wherein the first facet and the second facet have opposite surface polarity; and roughening a surface of the first facet, thereby fabricating a second nonpolar or semipolar III-Nitride based optoelectronic device.

The device prior to the roughening step may be a LD, and the device after the roughening step may be a SLD.

The roughening may be by wet etching, and an etch time and concentration of the electrolyte used in the wet etching may be varied to control feature size, density and total facet roughness of the first facet.

The present invention is applicable to SLD's emitting in any wavelength range, from ultraviolet (UV) to red light (e.g., SLDs emitting light having a wavelength from 280 nm or lower, through green light (e.g., 490-560 nm), and up to 700 nm, for example). UV emitting SLDs may use m-plane GaN SLDs, for example.

### BRIEF DESCRIPTION OF THE DRAWINGS

Referring now to the drawings in which like reference numbers represent corresponding parts throughout:

FIG. 1 is a flowchart illustrating a method of fabricating a device according to one or more embodiments of the present invention.

FIG. 2 shows scanning electron microscope (SEM) micrographs of the c⁻ facet after FIG. 2(a) 1, FIG. 2(b) 4, and FIG. 2(c) 8 hours in 2.2 M KOH, and FIG. 2(d) shows the c⁺ facet after 24 hours in 10 M KOH (for a different sample), demonstrating control over the roughness by varying etching conditions and the stability of the c⁺ facet.

FIG. 3 shows FIG. 3(a) a schematic diagram of the SLD and −c, m, a, and +c directions of III-Nitride, FIG. 3(b) transverse cross-section of the SLD in FIG. 3(a), and SEM images showing in FIG. 3(c) the −c facet of a device before KOH treatment, in FIG. 3(d) the −c facet after KOH treatment, and in FIG. 3(e) the +c facet after KOH treatment, wherein FIG. 3(c) was taken at a 40° angle to show surface morphology; also shown is a schematic of a cone on the roughened surface (FIG. 3(f)).

FIG. 4 shows spectra (light output intensity, arbitrary units (arb. units), versus wavelength in nanometers (nm)), for FIG. 4(a) a 4 μm ridge LD before KOH treatment, FIG. 4 (b) the same device after KOH treatment, FIG. 4 (c) the same device after KOH treatment but for emission below the substrate normal to the waveguide.

FIG. 5 plots FWHM (nanometers) of the SLD after KOH treatment, as a function of drive current (milliamps), for in-plane emission (circles) and backside emission (squares, also referred to as “below” in FIG. 5).

FIG. 6 shows luminescence versus current (L-I) characteristics (power output, (mW) versus current (mA)) of a LD before (circles), and SLD after KOH treatment (squares), wherein the dashed line is a guide for the eye for the LD data and the solid line is an exponential fit to the SLD data.

FIG. 7 shows FIG. 7(a) a schematic diagram of the detector set-up, and FIG. 7(b) spectrally integrated intensity as a function of current measured in-plane at the +c facet, and from the backside, wherein exponential (in-plane) and linear (backside) curves fitted to the data corresponding to current values above 100 mA are also shown, the onset of superluminescence can be estimated at around 100 mA, (4.76 kA/cm²) from the divergence of the integrated intensities measured in-plane and below the device due to stimulated emission along the waveguide, the in-plane emission can be fit well to an exponential curve with R² of 0.995, while the emission through the substrate can be fit by a linear function, and both fits were done for data above the onset of superluminescence (above 100 mA).

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### OVERVIEW

Crystallographic etching to form hexagonal pyramids has been demonstrated on the c⁻ facet of m-plane (In, Al, Ga)N, and SLD device fabrication has been demonstrated. This invention allows the fabrication of a low reflectance facet suitable for production of nonpolar (Ga,In,Al,B)N based SLDs.

In one embodiment of the present invention, the non-reflecting −c plane facet, intended to prevent optical feedback along the c-axis waveguide, was fabricated by KOH wet etching. KOH selectively etched the cleaved −c facet leading to the formation of hexagonal pyramids without etching the +c facet. The peak wavelength and FWHM were 439 nm and 9 nm at 315 mA, respectively, with an output power of 5 mW measured out of the +c facet.

### TECHNICAL DESCRIPTION

### Nomenclature

III-nitrides may be referred to as group III-nitrides, nitrides, or by (Al,Ga,In)N, AlInGaN, or Al_{(1-x-y)}In_{y}GaₓN where 0<x<1 and 0<y<1, for example.

These terms are intended to be broadly construed to include respective nitrides of the single species, Al, Ga, and In, as well as binary, ternary and quaternary compositions of such Group III metal species. Accordingly, the terms comprehend the compounds AlN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials. Boron may also be included in the III-nitride alloy.

Current nitride technology for electronic and optoelectronic devices employs nitride films grown along the polar c-direction. However, conventional c-plane quantum well structures in III-nitride based optoelectronic and electronic devices suffer from the undesirable quantum-confined Stark effect (QCSE), due to the existence of strong piezoelectric and spontaneous polarizations. The strong built-in electric fields along the c-direction cause spatial separation of electrons and holes that in turn give rise to restricted carrier recombination efficiency, reduced oscillator strength, and red-shifted emission.

One approach to eliminating the spontaneous and piezoelectric polarization effects in GaN or III-nitride optoelectronic devices is to grow the devices on nonpolar planes of the crystal. Such planes contain equal numbers of Ga and N atoms and are charge-neutral. Furthermore, subsequent nonpolar layers are equivalent to one another so the bulk crystal will not be polarized along the growth direction. Two such families of symmetry-equivalent nonpolar planes in GaN or III-nitride are the {11-20} family, known collectively as a-planes, and the {1-100} family, known collectively as m-planes.

Another approach to reducing or possibly eliminating the polarization effects in GaN optoelectronic devices is to grow the devices on semi-polar planes of the crystal. The term “semi-polar planes” can be used to refer to a wide variety of planes that possess both two nonzero h, i, or k Miller indices and a nonzero 1 Miller index. Thus, semipolar planes are defined as crystal planes with nonzero h or k or i index and a nonzero/index in the (hkil) Miller-Bravais indexing convention. Some commonly observed examples of semi-polar planes in c-plane GaN heteroepitaxy include the (11-22), (10-11), and (10-13) planes, which are found in the facets of pits. These planes also happen to be the same planes that the inventors have grown in the form of planar films. Other examples of semi-polar planes in the wurtzite crystal structure include, but are not limited to, (10-12), (20-21), and (10-14). The nitride crystal's polarization vector lies neither within such planes or normal to such planes, but rather lies at some angle inclined relative to the plane's surface normal. For example, the (10-11) and (10-13) planes are at 62.98° and 32.06° to the c-plane, respectively.

The Gallium, Ga face of GaN (or III-face of III-Nitride) is the +c, c⁺ or (0001) plane, and the Nitrogen or N-face of GaN or a III-nitride layer is the −c, c⁻ or (000-1) plane.

Process Steps

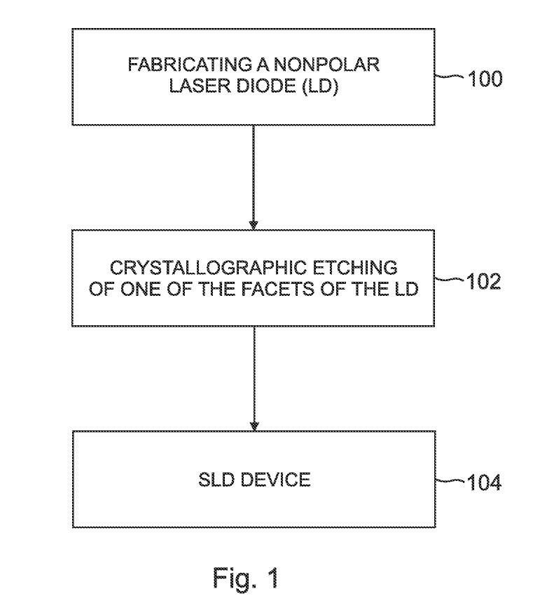

FIG. 1 illustrates a method of fabricating a device according to one or more embodiments of the present invention.

Block 100 represents obtaining or fabricating a nonpolar or semipolar (Ga,In,Al,B)N based optoelectronic device (e.g., LD) comprising an active region, a waveguide structure to provide optical confinement of light emitted from the active region, and a pair of facets. The pair of the facets may comprise a first facet and a second facet on opposite ends of the waveguide structure such that the first facet is opposite the second facet, and the first facet has an opposite surface polarity to the second facet.

The pair of facets having opposite surface polarities may comprise a c⁺ and a c⁻ facet, so that the opposite surface polarities are c⁺ and c⁻.

The facets may be formed by cleaving to achieve good directionality and far field pattern (FFP) for optical output from the c⁺ facet. However, the facets may also be formed by dry etching, focussed ion beam (FIB) based techniques, polishing or other methods. Either or both of the facets may be coated to increase or decrease the reflectivity of the output facet or suppress catastrophic optical damage (COD).

The device is tested at this point so that the L-I characteristics can be compared with the post treatment values, and superluminescence can be verified.

Block 102 represents roughening a surface of the first facet, e.g. crystallographic etching, wet etching, or PEC etching of one of the facets of the LD. After the step of Block 100, the LDs may be mounted face down using crystal-bond wax to protect the top side during KOH treatment. The topside protection may not be necessary but was done as a precaution. The mounted sample is then immersed in 2.2 M potassium hydroxide (KOH) for the desired time, typically between 1 and 24 hours.

The first facet may comprise a roughened c⁻ plane, c⁻ facet, or N-face of the III-Nitride device, and the second facet may comprise a c⁺ facet, c⁺ plane, Ga-face, or III-face of the III-Nitride device. The roughened surface of the first facet may be a roughened cleaved surface (a cleaved surface that is then roughened), and the second facet may have a cleaved surface.

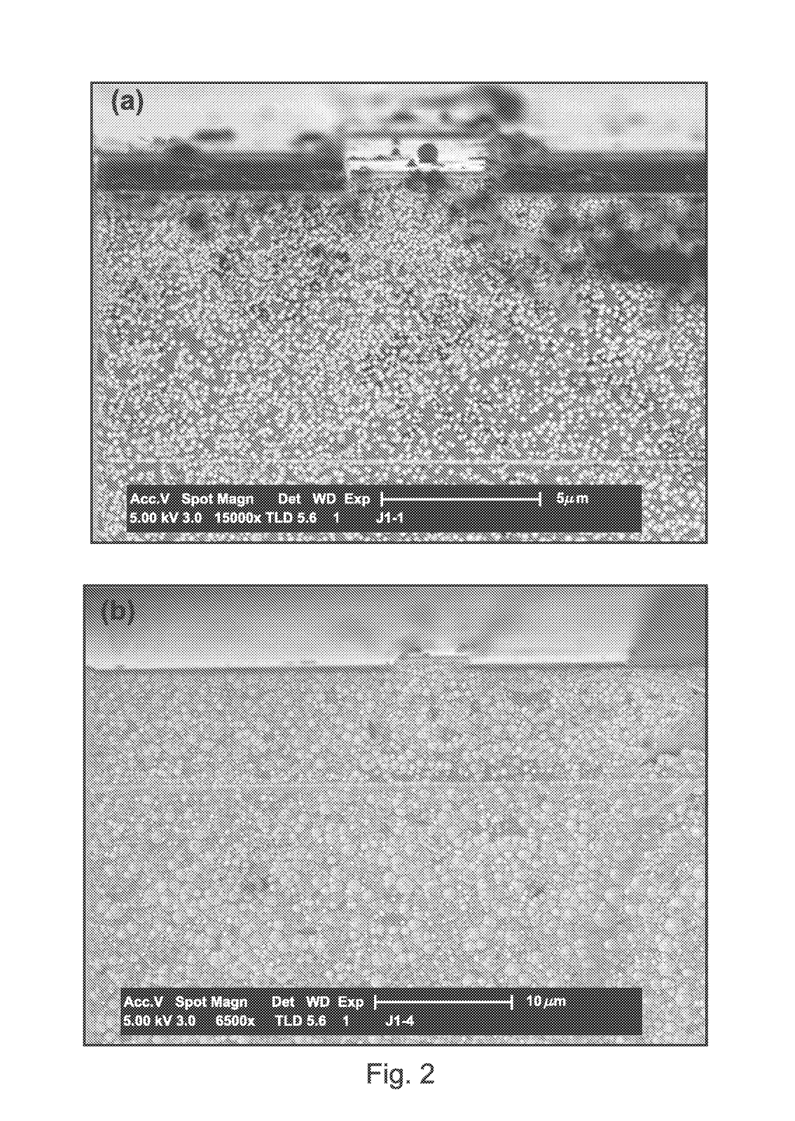

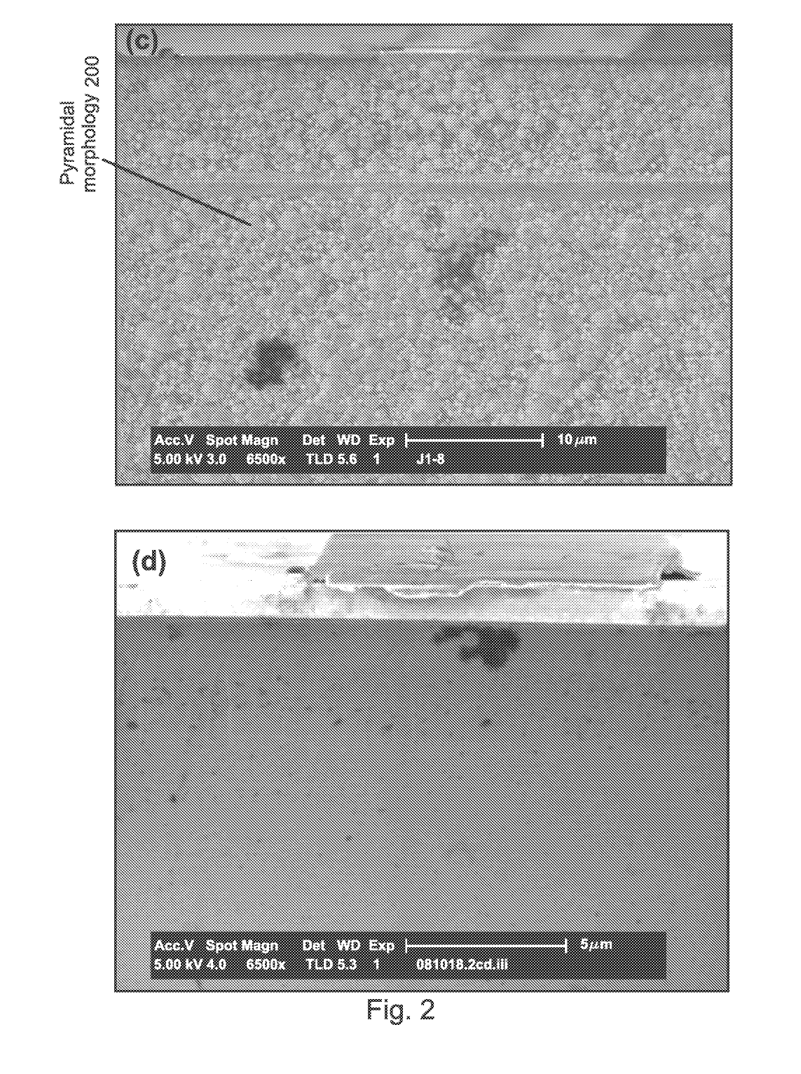

FIG. 2 shows the pyramidal morphology 200 after 1, 4, 8 and hours in KOH, as shown in FIGS. 2 (a), (b), and (c), respectively, and the lack of etching on the c⁺ facet, as shown in FIG. 2(d). PEC etching can be used to decrease the etch time by up to two orders of magnitude. The sample is then un-mounted and re-tested. No protection is necessary for the c⁺ facet because it does not etch in KOH under these conditions. Thus, the present invention may fabricate the SLD using the asymmetric chemical properties of the ±c facets. The pyramids 200 may have a base diameter and a height.

KOH crystallographic etching creates hexagonal pyramids comprising 6 {10-1-1} planes on the c⁻ facet of the device (5). Hence, the roughened surface may comprise hexagonal pyramids comprising a hexagonal base and 6 sidewalls that are {10-1-1}planes.

Other wet etching methods may be used, for example wet etching, crystallographic chemical etching, wet etching that results in crystallographic etching, or photoelectrochemical (PEC) etching. An etch time and concentration of the electrolyte used in the wet etching may be varied to control feature size, density and total facet roughness of the first facet.

Block 104 represents the end result of the method, a device such as an SLD. The SLD may comprise a structure for a (Ga,In,Al,B)N LD grown on nonpolar GaN, wherein a c⁻ facet of the LD structure is crystallographically etched. For example, the SLD may be an m-plane-GaN based blue SLD utilizing the asymmetric chemical properties of the ±c facets. The second facet may be an output facet of the SLD. For example, prior to the roughening step the device is a LD and after the roughening step the device is a SLD.

Light incident on internal facets of the pyramid can either pass through the internal facets or be reflected. Reflected light then encounters the opposing facet of the pyramid and again can either exit the device or be reflected. Given an uncoated interface between, for example, GaN and air, Fresnel reflection gives a reflection probability of 0.18. Thus, within 3 reflections, the amount of light remaining in the structure is already less than 1% of the incident light. Alternatively, simply increasing the roughness of the facet decreases reflectivity and increases mirror loss—which in turn increases the threshold current density. This effect is often used to increase the backside light extraction efficiency out the c⁻ facet of c-plane LEDs (8).

As the carrier density is increased in the active region of the LD, population inversion is achieved, leading to gain along the waveguide as stimulated emission amplifies the spontaneous emission in the device. In order for lasing to occur, the net round trip gain must be greater than the net round trip loss. However, by causing a large amount of light extraction (loss) at the c⁻ facet, optical feedback is suppressed. Amplification of stimulated emission occurs, leading to high optical output power, but coherence of the emitted light associated with lasing, is suppressed. Thus, the roughened surface may prevent optical feedback along an in-plane c-axis of the waveguide structure.

For example, the roughened surface may be such that no lasing peaks are observed in an emission spectrum of the SLD for drive currents up to 315 mA, wherein lasing peaks are observed in an identical structure without the roughened surface for drive currents above 100 mA. However, the specific currents required for superluminescence and/or lasing are largely set by the quality and dimensions of the device. For example, commercial blue LDs can have lasing currents below 50 mA. Therefore, the specific currents for superluminescence and/or lasing are not limited to particular values.

The roughened surface of the device may be such that a full width at half maximum (FWHM) of the light emitted by the SLD is at least 10 times larger than the device without the roughening (e.g., FWHM of the SLD 10 times larger than the FWHM for the LD). For example, the SLD may emit blue light and the roughened surface may be such that a FWHM of the light is greater than 9 nm.

The SLD may have an output power of at least 5 milliwatts. For example, the roughened surface may be such that an output power of the SLD increases exponentially with increasing drive current, in a linear gain regime of the SLD.

The waveguide structure may utilize index guiding or gain guiding to reduce internal loss, for example.

Device Structures and Experimental Results

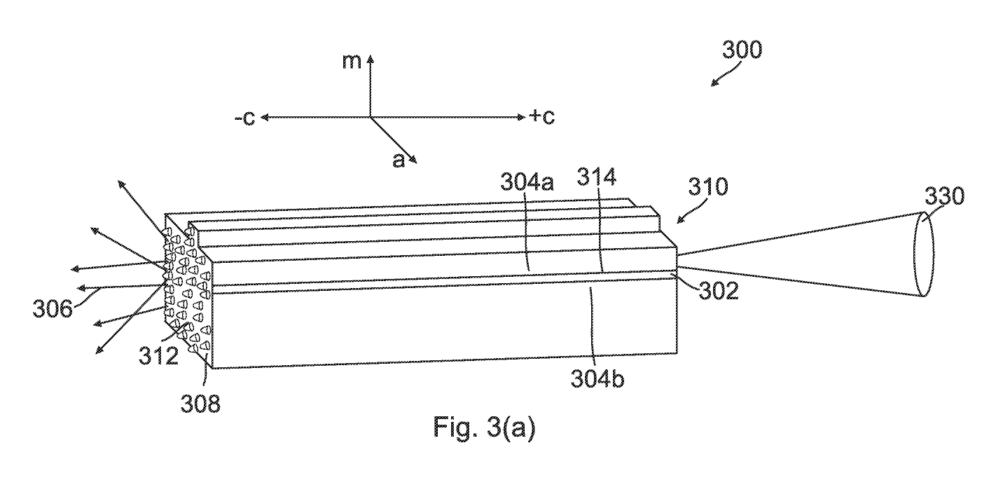

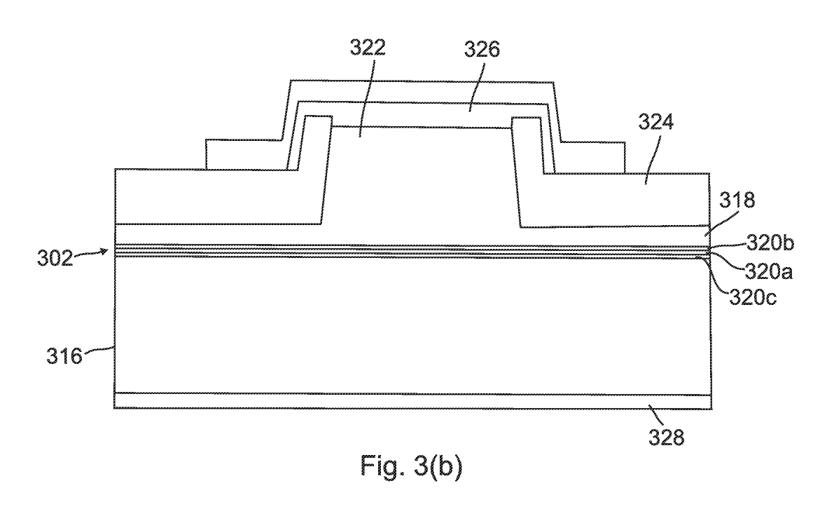

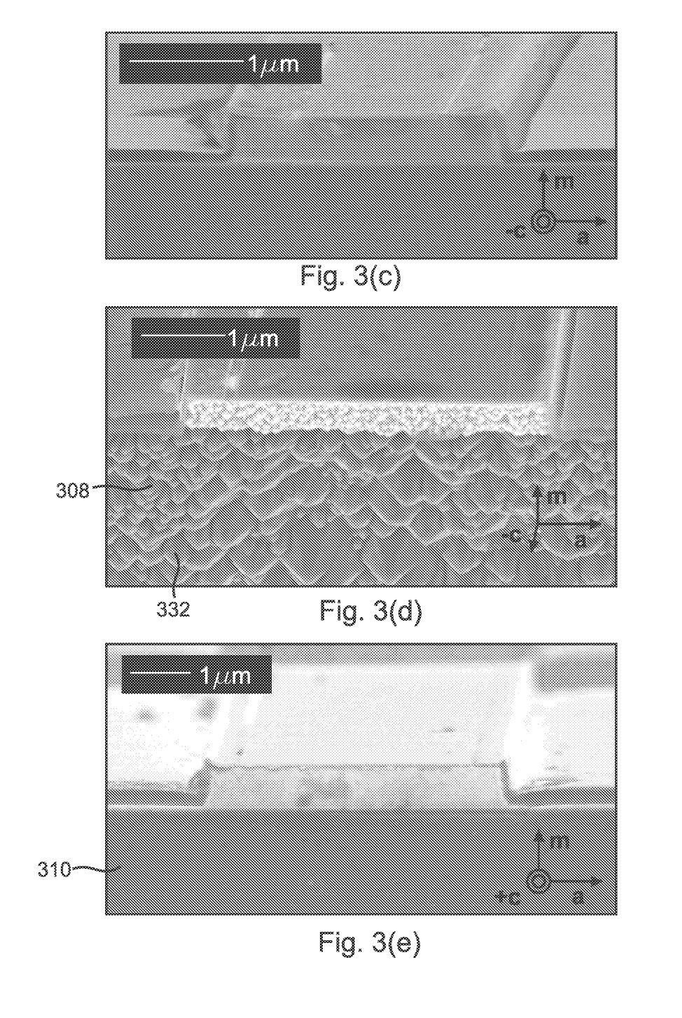

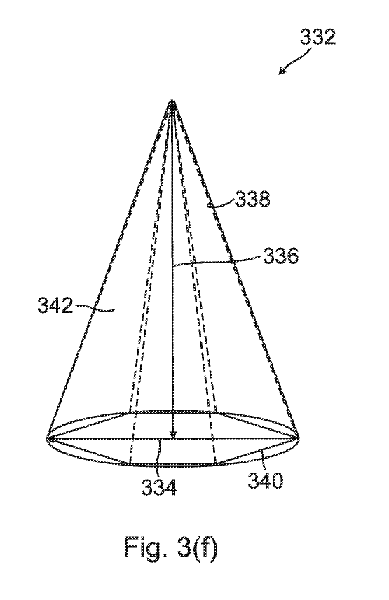

FIG. 3(a) shows a schematic diagram of a nonpolar or semipolar (Ga,In,Al,B)N or III-Nitride based optoelectronic device 300 (e.g., SLD), comprising an active region 302; a waveguide structure 304a, 304b to provide optical confinement of light 306 emitted from the active region 302; and a pair of facets including a first facet 308 and a second facet 310 on opposite ends of the waveguide structure 304a, 304b, such that the first facet 308 is opposite the second facet 310, wherein the first facet 308 and the second facet 310 have opposite surface polarity, and the first facet 308 has a roughened surface 312. The roughened first facet 308 is a c⁻ facet having a surface that is an N-polar plane that is roughened, and the second facet is a c⁺ facet.

The −c, m, a, and +c directions of III-Nitride are also shown (straight arrows in FIG. 3(a)), and the device 300 is grown along the m-direction. However, the device may also be grown along a semipolar direction. A growth plane (i.e., top surface or final growth plane of each device layer) 314 of the device 300 may be a nonpolar or semipolar plane. For example, the SLDs may be fabricated on a-planes of III-Nitride, or semi-polar planes of III-Nitride that are close to the c-plane of III-Nitride (e.g., 20-21 or 11-21 planes), thereby fabricating non-polar or semi-polar SLDs.

FIG. 3(b) is a transverse cross-section of the device of FIG. 3(a) illustrating n-type layers 316, p-type layers 318, and the active region 302 comprising quantum well 320a sandwiched between a first quantum barrier layer 320b and a second quantum well barrier layer 320c, wherein a thickness of the quantum well layer 320a is more than 4 nm.

The device of FIG. 3(a) was fabricated by first growing and fabricating an LD using standard techniques, as represented in Block 100 and (21). Specifically, an AlGaN-cladding-free LD structure was grown by standard metal-organic chemical vapor deposition on a bulk m-plane substrate (e.g., m-plane GaN) manufactured by Mitsubishi Chemical Company (18) (see also (22) and U.S. Utility application Ser. No. 12/030,117, filed on Feb. 12, 2008, by Daniel F. Feezell, Mathew C. Schmidt, Kwang Choong Kim, Robert M. Farrell, Daniel A. Cohen, James S. Speck, Steven P. DenBaars, and Shuji Nakamura, entitled “Al(x)Ga(1-x)N-CLADDING-FREE NONPOLAR GAN-BASED LASER DIODES AND LEDS,” attorneys' docket number 30794.222-US-U1 (2007-424)) The structure comprised of the n-type layers 316 (including a 4-μm-thick Si-doped GaN cladding layer, followed by 50 nm of Si-doped n-type InGaN waveguiding layer 304b). While FIG. 3(b) shows one period, the active region 302 actually fabricated comprised of a three period InGaN/InGaN multiple quantum well structure (however, any number of quantum wells or any quantum well composition is possible, e.g., InGaN/GaN quantum wells). An unintentionally doped GaN layer was grown on top the active region 302, followed by a 10-nm-thick Mg-doped Al_{0.25}Ga_{0.75}N electron blocking layer (EBL). The EBL was followed by p-type layers 318 (including a 50 nm Mg-doped p-type InGaN waveguiding layer 304a, a top cladding comprised of about 500-nm-thick Mg-doped p-type GaN, and 100 nm Mg-doped p++ contact layer capping the structure). A 4 μm wide stripe or ridge 322 was formed by patterning and dry etching ridges along the c-direction.

A standard liftoff process was used for the oxide insulator 324, followed by Pd/Au metal deposition for cathode electrodes 326. The facets 308, 310 were formed by cleaving, resulting in a cavity length of 500 μm, and Indium was used to from the backside anode electrode 328. Then, the first facet 308 was roughened, as represented in Block 102. In-plane output power 330 of the light 306 may be measured from the c+ facet 310.

FIG. 3(c)-(e) are SEM images of the device, showing FIG. 3(c) the −c facet of a device before KOH treatment, FIG. 3(d) the −c facet after KOH treatment (device of FIG. 3(a)), and FIG. 3(e) the +c facet after KOH treatment (device of FIG. 3(a)), wherein FIG. 3(c) was taken at a 40° angle to show surface morphology.

The SEM images show the formation of hexagonal pyramids 332 only on the −c facet, wherein the roughened surface comprises one or more hexagonal pyramids having a base diameter between 0.1 and 1.6 micrometers (hexagonal pyramid base diameter ranges from 0.3 to 1.6 μm on the n-type GaN, and from 100 to 150 nm on the p-type GaN). However, the roughened surface is not limited to any particular dimensions or features (including base diameters of 10 micrometers or more, using heated or PEC etching, for example).

For example, FIG. 3(f) shows the roughened surface may comprise one or more structures (e.g., cones 332) having a base diameter 334 and a height 336, wherein the base diameter 334 may be 10 micrometers or more, for example. The base diameter 334 and/or height 336 may be sufficiently close to a wavelength of the light that the structures scatter the light out of the SLD. Also shown in FIG. 3(f) is how the structures may be hexagonal pyramids 338 with hexagonal base 340 and {10-1-1} plane sidewalls 342, wherein the hexagonal pyramids 338 are cone-shaped 332. If a sidewall 342 forms a {10-1-1} plane, the angle of the {10-1-1} plane is 62 degrees relative to the c-plane.

In some embodiments, the entire surface of the c⁻ facet 308 is covered with cones, and in some embodiments, larger cones 332 are better.

Device Performance

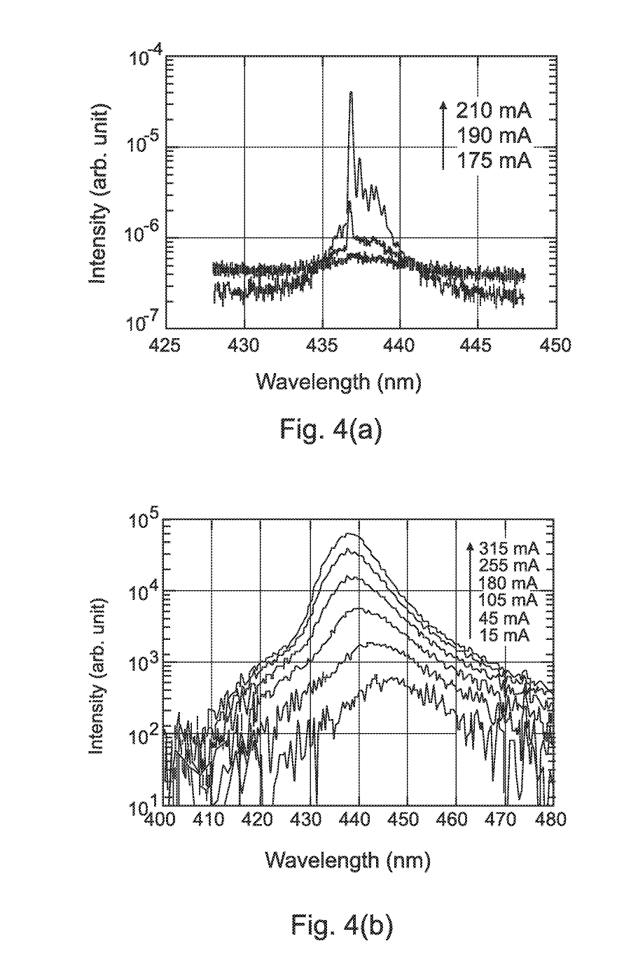

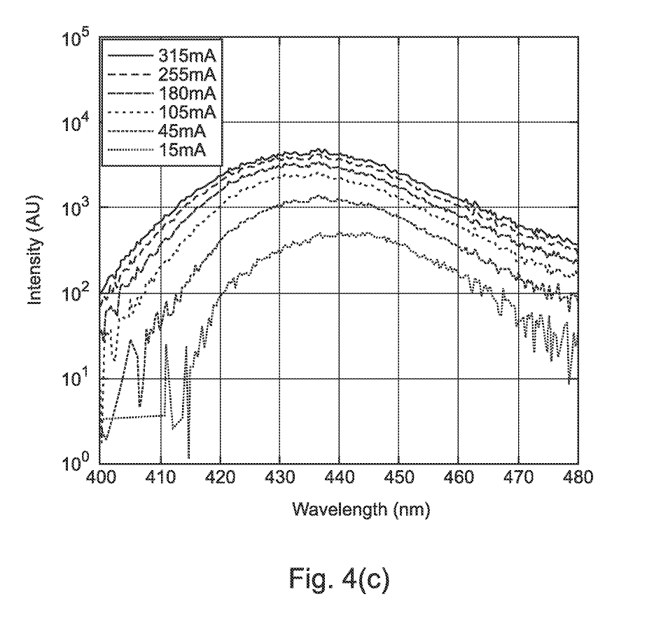

FIG. 4 shows spectra (light output intensity, arbitrary units (arb. units), versus wavelength in nanometers (nm)), for different drive currents (mA), for FIG. 4(a) a 4 μm ridge LD before KOH treatment (bottom curve to top curve are for drive currents 175 mA, 190 mA, and 210 mA, respectively), FIG. 4 (b) the same device (device of FIG. 3(a)) after KOH treatment (bottom curve to top curve are for drive currents 15 mA, 45 mA, 105 mA, 180 mA, 255 mA, and 315 mA, respectively), for in-plane emission, and FIG. 4(c) the same device (device of FIG. 3(a)) after KOH treatment but for emission below the substrate and normal to the waveguide.

Before KOH treatment, lasing peaks were observed at injection currents as low as 190 mA (9.05 kA/cm²), with a peak wavelength of 436.8 nm, and the full width at half maximum intensity (FWHM) for the LD is 0.3 nm at 190 mA just above threshold.

Spectral width narrows for the device after KOH treatment with increasing drive current due to the presence of stimulated emission in the waveguide, however no sharp peak in the spectra due to lasing is observed over the current range presented. The minimum FWHM for the SLD is 9 nm at 315 mA, almost an order of magnitude higher than that of the LD, and the peak wavelength was 439 nm.

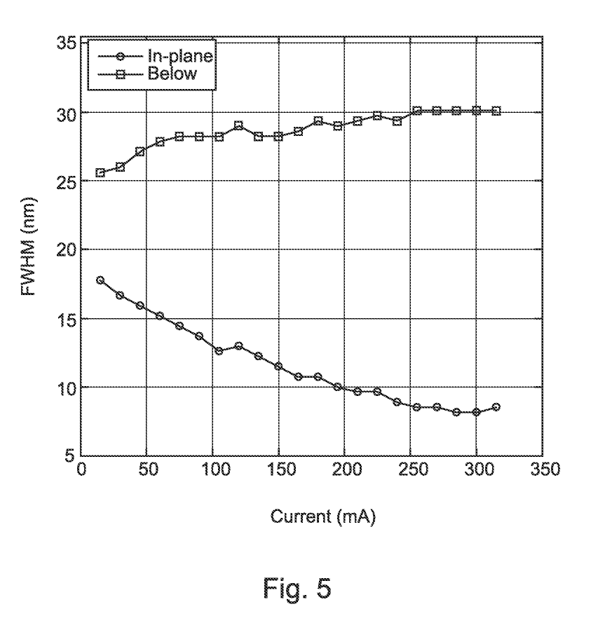

FIG. 5 measures the FWHM of the device of FIG. 3(a), and illustrates the roughened surface of the device may be such that a FWHM of the light emitted by the SLD is at least 10 times larger than the device without the roughening (e.g., FWHM of the SLD 10 times larger than the FWHM for the LD). In FIG. 5, the SLD shows a minimum FWHM of 8 nm, whereas a typical LD FWHM is 0.2 nm. The SLD does not evidence strong wavelength selection due to resonance in the optical cavity.

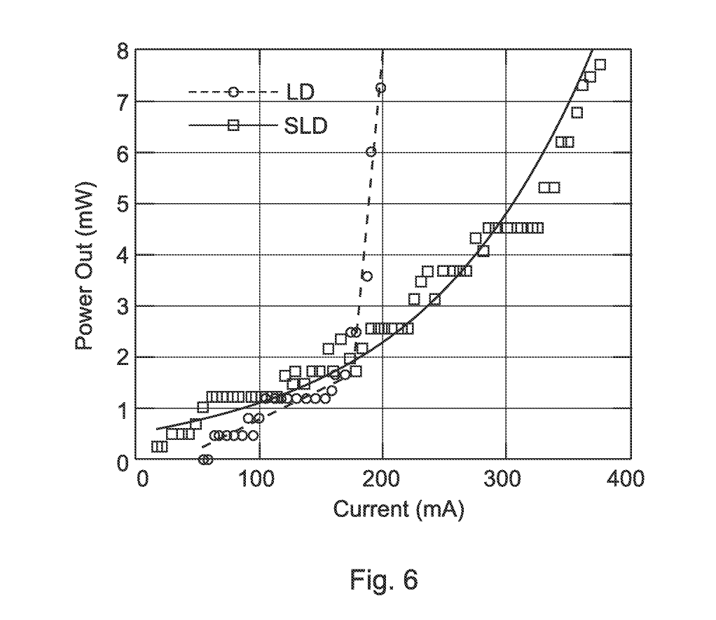

FIG. 6 shows L-I characteristics of a LD before, and SLD after KOH treatment (device of FIG. 3(a)), wherein the dashed line is a guide for the eye for the LD data and the solid line is an exponential fit to the SLD data. Before KOH treatment, the L-I curve showed a very sharp lasing threshold with a linear increase in output power above threshold.

The output power for the SLD measured out of the +c facet reached approximately 5 mW. The output power after KOH treatment increased exponentially as a function of current, as expected for a SLD in the linear gain regime.

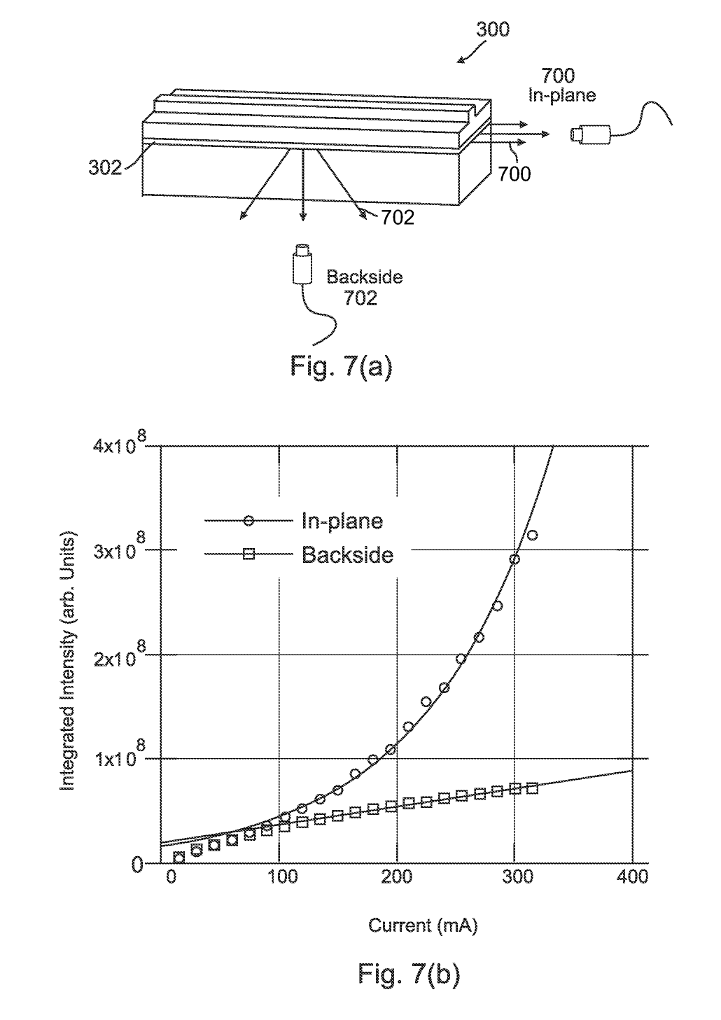

FIG. 7 shows FIG. 7(a) a schematic diagram of the detector set-up and FIG. 7(b) spectrally integrated intensity of the SLD emission as a function of current (using the device of FIG. 3(a)), measured for in-plane 700 emission at the +c facet, and emission from the backside 702, wherein exponential (in-plane) and linear (backside) curves fitted to the data corresponding to current values above 100 mA are also shown. The integrated intensity was measured using an optical fiber coupled to a detector placed in-plane 700 at the +c facet (in-plane) and below the device normal to the waveguide (backside 702). The in-plane 700 emission comprises both spontaneous and stimulated emission due to amplification in the waveguide, while backside 702 emission measures only spontaneous emission transmitted through the substrate.

The divergence of the in-plane emission from the backside emission indicates the onset of superluminescence just below 100 mA. This occurs due to gain, resulting from stimulated emission along the waveguide, causing the measured in-plane intensity to increase exponentially, while the backside emission, which comprises of only spontaneous emission, remains linear. Note also that below the onset of superluminescence both the in-plane and backside emission divert linearly from the fits above the onset due to the change in emission mechanism.

(Ga,In,Al,B)N SLDs would be best fabricated on bulk nonpolar or semipolar substrates (e.g., III-Nitride or GaN substrates), to take advantage of the enhanced optical and electrical properties resulting from epitaxial growth on these substrates. However, the invention can also be used for any device having c-plane facets, grown on any substrate.

Applications of the present invention's SLDs include, but are not limited to, light sources for pico projectors and retinal scanning displays in the blue to green spectral region (and possibly beyond) with tunable mirror loss, high power directional solid state lighting and fiber coupled lighting.

Possible Modifications

A crystallographic chemical etching process may be used to roughen the first facet (c-facet). For example, the crystallographic chemical etching process may use KOH at room temperature, or heated. However, other wet etching processes that result in crystallographic etching can also be used as the crystallographic chemical etching process. The etch time and concentration of the electrolyte can be varied to control feature size, density and total facet roughness of the first facet 308.

Thus any etch chemistry that results in crystallographic etching is covered by the scope of this invention, including the use of PEC etching techniques as the crystallographic etching process. PEC etching rates are typically 1 to 2 orders of magnitude faster than non-illuminated etching and may provide higher throughput, if the top side can be adequately protected.

Some photoresist developers, such as AZ 726 MIF may also be used during the etching process (e.g., during the crystallographic chemical etching process). For example, some photoresist developers may also be used to crystallographically etch N-face GaN. Due to the general chemical reactivity of N-face GaN, it is likely there will be other etch chemistries which will cause crystallographic etching and can also be used to form a non-reflecting facet as described above.

Thus, the optoelectronic device of the present invention may comprise an active region and a waveguide structure to provide optical confinement of light emitted from the active region; a pair of facets on opposite ends of the device, having opposite surface polarity. The device may be a nonpolar or semipolar (Ga,In,Al,B)N based device (i.e., the growth plane of the device is typically nonpolar or semipolar and the facet polarities typically correspond to the c⁺ and c⁻ facet).

The facets may be formed by cleaving to achieve good directionality and far field pattern (FFP) for optical output from the c⁺ facet. The facets can also be formed by dry etching, focussed ion beam (FIB) based techniques, polishing or other methods. Facet coating to increase or decrease the reflectivity of the output facet, or suppress catastrophic optical damage (COD) for either facet can be used.

One of the facets may then be roughened by a crystallographic chemical etching process, where the roughened facet is the c Nitrogen-polar (N-polar) plane.

The waveguide structure may utilize index guiding or gain guiding to reduce internal loss, for example.

The present invention includes the option of putting an anti-reflective coating on the +c facet if there are too many reflections. Coating the front side may also improve device performance.

Also, the stripe 322 can be angled between the facets to further reduce reflections off both facets, which may improve performance.

### ADVANTAGES AND IMPROVEMENTS

This invention features a novel mechanism, crystallographically etched light extraction cones, for forming a non-reflecting facet suitable for use in (Ga,In,Al,B)N SLDs. This wet etch step can be added to a standard LD fabrication process to allow SLD fabrication with minimal process development. For example, this invention allows manufacture of SLDs from any nonpolar (Ga,In,Al,B)N LD process with c-plane cleaved facets, by the addition of only one relatively inexpensive and straight forward processing step. This method of forming a low reflection facet does not require any sacrifice in device packing density on wafer, and does not require any processing steps incompatible with normal laser processing. This technique allows any nonpolar (Ga,In,Al,B)N laser process to be adapted directly for the manufacture of SLDs without needing to re-optimize or change any processing steps. Thus industrial application of this technique as a batch based wet etching step promises to be low in cost relative to other fabrication methods.

SLDs are can act as the light source for pico projectors and scanning retinal displays (9) due to their relatively large spectral width, directional output and relatively high power.

The present invention provides the advantage of fabricating SLDs with an ease of manufacturing, and scalability.

### REFERENCES

The following references are incorporated by reference herein.
(1) “AlGaN-Cladding-Free Nonpolar InGaN/GaN Laser Diodes,” by Feezell, D. F., et al., Jpn. J. Appl. Phys., Vol. 46, pp. L284-L286 (2007).
(2) “Continuous-wave Operation of AlGaN-cladding-free Nonpolar m-Plane InGaN/GaN Laser Diodes,” by Farrell, R. M., et al., Jpn. J. Appl. Phys., Vol. 46, pp. L761-L763 (2007).
(3) “Reduction of Threshold Current Density of Wurtzite GaN/AlGaN Quantum Well Lasers by Uniaxial Strain in (0001) Plane,” by Suzuki, Masakatsu and Uenoyama, Takeshi.: The Japan Society of Applied Physics, Jpn. J. Appl. Phys., Vol. 35, pp. L953-L955 (1996).
(4) “Continuous-Wave Operation of m-Plane InGaN Multiple Quantum Well Laser Diodes,” by Okamoto, Kuniyoshi, et al.: The Japan Society of Applied Physics, Japanese Journal of Applied Physics, Vol. 46, pp. L187-L189 (2007).
(5) “Roughening Hexagonal Surface Morphology on Laser Lift-Off (LLO) N-Face GaN with Simple Photo-Enhanced Chemical Wet Etching,” by Gao, Yan, et al., Jap. J. Appl. Phys., Vol. 43, p. L637 (2004).
(6) “Dislocation- and crystallographic-dependent photoelectrochemical wet etching of gallium nitride,” by Gao, Y., et al.: AIP, Applied Physics Letters, Vol. 84, pp. 3322-3324 (2004).
(7) “A stripe-geometry double-heterostructure amplified-spontaneous-emission (superluminescent) diode,” by Lee, Tien-Pei, Burrus, C. and Miller, B., IEEE J. Quantum. Electron., Vol. 9, pp. 820-828 (1973).
(8) “Cone-shaped surface GaN-based light-emitting diodes,” Fujii, T., et al., physica status solidi (c), Vol. 2, pp. 2836-2840 (2005).
(9) “Development of a commercial retinal scanning display,” by Johnston, Richard S. and Willey, Stephen R.: SPIE, Proc. SPIE, Vol. 2465, pp. 2-13 (1995).
(10) “High-Efficiency Continuous-Wave Operation of Blue-Green Laser Diodes Based on Nonpolar m-Plane Gallium Nitride,” by Okamoto, Kuniyoshi, Tanaka, Taketoshi and Kubota, Masashi., Appl. Phys. Express, Vol. 1, p. 072201 (2008).
(11) “Nonpolar m-plane InGaN multiple quantum well laser diodes with a lasing wavelength of 499.8 nm,” by Okamoto, Kuniyoshi, et al. s. l., AIP, Appl. Phys. Lett., Vol. 94, p. 071105 (2009).
(12) “Increase in the extraction efficiency of GaN-based light-emitting diodes via surface roughening,” Fujii, T., et al., AIP, Applied Physics Letters, Vol. 84, pp. 855-857 (2004).
(13) U.S. Pat. No. 4,901,123, issued Feb. 13, 1990, by Noguchi et. al.
(14) U.S. Pat. No. 5,223,722, issued Jun. 29, 1993, by Nagai et. al.
(15) U.S. Pat. No. 4,896,195, issued Jan. 23, 1990, by Jansen et. al.
(16) U.S. Pat. No. 4,958,355, issued Sep. 18, 1990, by Alphonse et. al.
(17)“m-plane GaN-based Blue Superluminescent Diodes Fabricated Using Selective Chemical Wet Etching,” by Matthew T. Hardy, Kathryn M. Kelchner, You-Da Lin, Po Shan Hsu, Kenji Fujito, Hiroaki Ohta, James S. Speck, Shuji Nakamura, and Steven P. DenBaars.
(18) K. M. Kelchner, Y. D. Lin, M. T. Hardy, C. Y. Huang, P. S. Hsu, R. M. Farrell, D. A. Haeger, H. C. Kuo, F. Wu, K. Fujito, D. A. Cohen, A. Chakraborty, H. Ohta, J. S. Speck, S. Nakamura and S. P. DenBaars: Appl. Phys. Express 2 (2009) 071003.
(20). Presentation Slides given by Shuji Nakamura, entitled “An overview of Laser Diodes (LDs) and Light Emitting Diodes (LEDs) Research at SSLEC,” at the 2009 Annual Review for Solid State Lighting and Energy Center (SSLEC), University of California, Santa Barbara (Nov. 5, 2009).
(21). Presentation Slides given by Matthew T. Hardy, entitled “Backend Processing for m-plane Cleaved Facet Laser Diodes and Superluminescent Diodes,” at the 2009 Annual Review for SSLEC, University of California, Santa Barbara (Nov. 6, 2009).
(22) Presentation Slides given by Kate Kelchner at the 2009 Annual Review for SSLEC, entitled “Continuous Wave Technology for Pure Blue Laser Diodes on Nonpolar m-plane GaN,” Nov. 6, 2009, University of California, Santa Barbara.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A nonpolar or semipolar III-Nitride based optoelectronic device, comprising:
an active region;
a waveguide structure to provide optical confinement of light emitted from the active region; and
a first facet and a second facet on opposite ends of the waveguide structure, wherein the first facet and the second facet have opposite surface polarity and the first facet has a roughened surface.

2. The device of claim 1, wherein the first facet comprises a roughened c⁻ facet, c⁻ plane, or N-face of the III-Nitride device, and the second facet is a c⁺ facet, c⁺ plane, III-face, or Ga face of III-the Nitride device.

3. The device of claim 2, wherein the roughened surface is a wet etched surface.

4. The device of claim 2, wherein the roughened surface is a crystallographically etched surface.

5. The device of claim 2, wherein the roughened surface is a photoelectrochemically (PEC) etched surface.

6. The device of claim 2, wherein the roughened surface is a roughened cleaved surface, and the second facet has a cleaved surface.

7. The device of claim 2, wherein the roughened surface prevents optical feedback along an in-plane c-axis of the waveguide structure.

8. The device of claim 2, wherein the roughened surface comprises one or more structures having a diameter and height sufficiently close to a wavelength of the light that the structures scatter the light out of the waveguide.

9. The device of claim 2, wherein the roughened surface comprises one or more hexagonal pyramids having a diameter between 0.1 and 10 micrometers.

10. The device of claim 2, with an output power of at least 5 milliwatts.

11. The device of claim 2, wherein the device is a superluminescent diode (SLD).

12. The device of claim 11, wherein the roughened surface is such that an output power of the SLD increases exponentially with increasing drive current, in a linear gain regime of the SLD.

13. The device of claim 11, wherein the roughened surface is such that a full width at half maximum of the light emitted by the SLD is at least 10 times larger than without the roughening.

14. The device of claim 11, wherein the SLD emits blue light and the roughened surface is such that a full width at half maximum of the light is greater than 9 nm.

15. The device of claim 1, wherein the waveguide structure utilizes index guiding or gain guiding to reduce internal loss.

16. A method of fabricating a nonpolar or semipolar III-Nitride based optoelectronic device, comprising:
obtaining a first nonpolar or semipolar III-Nitride based optoelectronic device comprising an active region, a waveguide structure to provide optical confinement of light emitted from the active region, and a first facet and a second facet on opposite ends of the waveguide structure, wherein the first facet and the second facet have opposite surface polarity; and
roughening a surface of the first facet, thereby fabricating a second nonpolar or semipolar III-Nitride based optoelectronic device.

17. The method of claim 16, wherein the first facet comprises a roughened c⁻ plane, c⁻ facet, or N-face of the III-Nitride device, and the second facet is a c⁺ facet, c⁺ plane, Ga face or III-face of the III-Nitride device.

18. The method of claim 17, wherein the roughening is by wet etching that results in crystallographic etching.

19. The method of claim 18, wherein an etch time and concentration of the electrolyte used in the wet etching is varied to control feature size, density and total facet roughness of the first facet.

20. The method of claim 17, wherein the roughening is by a crystallographic chemical etching process.

21. The method of claim 20, wherein the crystallographic chemical etching process uses KOH at room temperature or heated.

22. The method of claim 20, wherein a photoresist developer comprising AZ 726 MIF is used during the crystallographic chemical etching process.

23. The method of claim 17, the roughening is by photoelectrochemical (PEC) etching.

24. The method of claim 17, wherein the first and second facets are formed by cleaving prior to the roughening, so that the second facet has a cleaved surface and the roughened surface is formed by roughening the first facet that has been cleaved.

25. The method of claim 17, wherein the first facet and second facet are formed by dry etching, focused ion beam (FIB) based techniques, or polishing, prior to the roughening step.

26. The method of claim 17, wherein the roughened surface prevents optical feedback along an in-plane c-axis of the waveguide structure.

27. The method of claim 17, wherein the roughened surface comprises one or more structures having a diameter and height sufficiently close to a wavelength of the light that the structures scatter the light out of the waveguide.

28. The method of claim 17, wherein the roughened surface comprises one or more hexagonal pyramids having a diameter between 0.1 and 10 micrometers.

29. The method of claim 17, with an output power of at least 5 milliwatts.

30. The method of claim 17, wherein the first device prior to the roughening step is a laser diode and the second device after the roughening step is a superluminescent diode (SLD).

31. The method of claim 30, wherein the roughened surface is such that an output power of the SLD increases exponentially with increasing drive current, in a linear gain regime of the SLD.

32. The method of claim 30, wherein the roughened surface is such that a full width at half maximum of the light emitted by the SLD is at least 10 times larger than without the roughening.

33. The method of claim 30, wherein the SLD emits blue light and the roughened surface is such that a full width at half maximum of the light is greater than 9 nm.

34. The method of claim 17, wherein the waveguide structure utilizes index guiding or gain guiding to reduce internal loss.

35. A superluminescent diode (SLDs), comprising:
a structure for a (Ga,In,Al,B)N laser diode (LD) grown on nonpolar GaN, wherein a c⁻ facet of the LD structure is crystallographically etched.
